(19) United States
(12) Patent Application Publication
(10) Pub. No.: US 2023/0174373 A1
(43) Pub. Date: Jun. 8, 2023

(54) SEALED CAVITY STRUCTURE AND METHOD FOR MANUFACTURING SEALED CAVITY STRUCTURE

(71) Applicant: AAC ACOUSTIC TECHNOLOGIES (SHENZHEN) CO., LTD., Shenzhen (CN)

(72) Inventors: Wooicheang Goh, Singapore (SG); Kahkeen Lai, Singapore (SG)

(21) Appl. No.: 17/742,425

(22) Filed: May 12, 2022

(30) Foreign Application Priority Data
Dec. 3, 2021 (CN) 202111472312.9

(51) Int. Cl. B81C 1/00; B81B 7/00

(52) U.S. Cl. CPC B81C 1/00269; B81B 7/0054; B81B 2201/0257; B81C 2203/019; B81C 2201/013; B81B 2203/0127

(57) ABSTRACT

Provided is a sealed cavity structure, including a base; an upper cover fixed to the base in a covering manner and defining a cavity jointly with the base; a leak hole that passes through the upper cover and communicates the cavity with outside; a sealing cover plate attached and fixed to an outer surface of the upper cover and completely covering the leak hole to seal the leak hole; and a sealing cap including a cap wall pressed on a side of the sealing cover plate away from the leak hole and a cap sidewall extending from the cap wall toward a direction close to the upper cover and fixed, in an abutting manner, to the upper cover. A method for manufacturing a sealed cavity structure is further provided. In this technical solution, better sealing reliability can be achieved.

### TECHNICAL FIELD

The present invention relates to the technical field of Micro-Electro-Mechanical System (MEMS) microphones, and in particular, to a sealed cavity structure for MEMS microphones and a method for manufacturing a sealed cavity structure.

### BACKGROUND

With the development of mobile Internet, the number of intelligent mobile devices continues to rise. Mobile phones are undoubtedly the most common and portable mobile terminal devices. MEMS microphones for obtaining external sound are widely used in existing intelligent mobile devices such as mobile phones.

The MEMS microphone in the related art includes a sealed cavity structure for mounting an MEMS chip, and reliability of the sealed cavity structure is the key to ensure that the MEMS microphone can operate according to design requirements under required pressure and conditions. In the related art, the sealed cavity structure is formed by depositing one or more layers of sealing materials at a top of the leak hole. Such a structure is quite simple, however, the sealing material does not cover a part of the leak hole and an sidewall thereof, increasing the overall stress on the sealed cavity structure, thereby reducing the sealing reliability of the sealed cavity structure.

Therefore, there is a need to provide a new sealed cavity structure and a method for manufacturing a sealed cavity structure to solve the above technical problems.

### SUMMARY

An objective of the present invention is to provide a sealed cavity structure with good sealing reliability and a method for manufacturing a sealed cavity structure.

In order to achieve the above objective, according to an embodiment of the present invention, a method for manufacturing a sealed cavity structure is provided, and the method includes steps of:

providing a base;

depositing a sacrificial layer on an upper surface of the base;

etching a periphery of the sacrificial layer to cause the periphery of the sacrificial layer to retract inward to a range of the base to form an avoiding space;

depositing an upper cover on an upper surface of the sacrificial layer, such that the upper cover supports and fixes the base via the avoiding space and is completely attached to the upper surface of the sacrificial layer and a peripheral side of the sacrificial layer;

etching the upper cover, such that a leak hole that passes through the upper cover is formed;

releasing the sacrificial layer, such that the upper cover and the base jointly define a cavity, and the leak hole communicates the cavity with outside;

depositing a first sealing material layer on an outer surface of a side of the upper cover directly opposite to the base, such that the first sealing material layer seals the leak hole;

etching the first sealing material layer to form a ring-shaped separation groove, the ring-shaped separation groove dividing the first sealing material layer into a first part and a second part surrounding the first part, the first part serving as a sealing cover plate and completely covers the leak hole;

depositing a second sealing material layer on an upper surface of the first sealing material layer, and filling up the separation groove with the second sealing material layer;

etching a periphery of the second sealing material layer to cause the periphery of the second sealing material layer to retract inward into a range of the second part, so as to serve as a sealing cap; and

releasing the second part of the first sealing material layer to obtain the sealed cavity structure.

The present invention further provides a sealed cavity structure, including:

a base;

an upper cover, the upper cover covering and being fixed to the base, and the cover and the base jointly defining a cavity;

a leak hole, the leak hole passing through the upper cover and communicating the cavity with outside;

a sealing cover plate, the sealing cover plate being attached and fixed to an outer surface of the upper cover and completely covering the leak hole to seal the leak hole; and

a sealing cap, the sealing cap including a cap wall pressed on a side of the sealing cover plate away from the leak hole and a cap sidewall extending from the cap wall toward a direction close to the upper cover and fixed, in an abutting manner, to the upper cover. The cap sidewall is in a shape of a ring and attached to a peripheral side of the sealing cover plate. An orthographic projection of the cap wall onto the upper cover along a leakage direction of the leak hole is completely within a range of the upper cover. Along a direction perpendicular to the leakage direction, an outer peripheral side of the cap sidewall is closer to the sealing cover plate than an outer peripheral side of the cap wall.

In an improved embodiment, the upper cover includes an upper cover body directly opposite to and spaced from the base and an upper cover extension wall extending from a periphery of the upper cover body toward a direction close to the base and fixed, in an abutting manner, to the base, and the leak hole passes through the upper cover body, the sealing cover plate is attached and fixed to the upper cover body, and an orthographic projection of the cap wall onto the upper cover is completely within a range of the upper cover body.

In an improved embodiment, an area of the cap wall is smaller than an area of the upper cover body.

In an improved embodiment, the upper cover is of a cube structure, and the sealing cover plate is of a cylinder structure.

In an improved embodiment, the sealed cavity structure is manufactured by the method for manufacturing the sealed cavity structure described above.

Compared with the related art, according to the method for manufacturing a sealed cavity structure and a sealed cavity structure in the present invention, the leak hole is completely sealed by the sealing cover plate, a sealing cover is covered by a sealing cap to sleeve the sealing cover plate, and the structure of the sealing cap is more solid and reliable; moreover, an orthographic projection of the upper cover of the sealing cap is completely within a range of the upper cover body, equivalent to removing excessive materials of the sealing cap, realizing abutment against a peripheral side of the sealing cover plate in conjunction with the sealing cap, thereby greatly reducing an influence of residual stress on the sealing cover plate, and thus effectively improving the sealing reliability of the sealed cavity structure.

### BRIEF DESCRIPTION OF DRAWINGS

In order to more clearly illustrate technical solutions in embodiments of the present invention, the accompanying drawings used in the embodiments are briefly introduced as follows. It should be noted that the drawings described as follows are merely part of the embodiments of the present invention, other drawings can also be acquired by those skilled in the art without paying creative efforts.

FIG. 1 is a schematic diagram of a sealed cavity structure according to an embodiment of the present invention; and

FIG. 2 is a schematic flow diagram of a method for manufacturing a sealed cavity structure according to an embodiment of the present invention.

### DESCRIPTION OF EMBODIMENTS

The technical solutions in the embodiments of the present invention will be described clearly and completely below with reference to the accompanying drawings in the embodiments of the present invention. It is apparent that the described embodiments are merely some of rather than all of the embodiments of the present invention. All other embodiments acquired by those of ordinary skill in the art without creative efforts based on the embodiments in the present invention fall within the protection scope of the present invention.

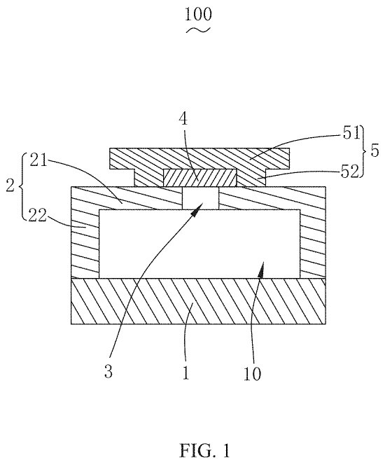

FIG. 1 is a schematic diagram of a sealed cavity structure according to an embodiment of the present invention. An embodiment of the present invention provides a sealed cavity structure 100, including: a base 1, an upper cover 2, a leak hole 3, a sealing cover plate 4, and a sealing cap 5.

The base 1 is formed from a base material, such as a silicon-based material.

The upper cover 2 covers the base 1 and is fixed to the base 1, and the upper cover 2 and the base 12 jointly define a cavity 10

The leak hole 3 passes through the upper cover 2, and communicates the cavity 10 with outside.

The sealing cover plate 4 is attached and fixed to an outer surface of the upper cover 2 and completely covers the leak hole 3 to seal the leak hole 3, such that the cavity 10 forms a sealed space.

In an embodiment of the present invention, the upper cover 2 is of a cube structure, the sealing cover plate 4 is of a cylinder structure, and the leak hole 3 is in a shape of a circle. Certainly, the shapes are not limited thereto, and may also be other shapes.

The sealing cap 5 includes a cap wall 51 pressed on a side of the sealing cover plate 4 away from the leak hole 3 and a cap sidewall 52 extending from the cap wall 51 toward a direction close to the upper cover 2 and fixed, in an abutting manner, to the upper cover 2.

The cap sidewall 52 is in a shape of a ring and attached to a peripheral side of the sealing cover plate 4. That is, the cap sidewall 52 is sleeved on the sealing cover plate 4, such that the structure of the sealing cover plate 4 is solid and reliable, and the influence of residual stress on the sealing cover plate 4 is greatly reduced, thereby effectively improving the sealing reliability of the leak hole 3 by the sealed cavity structure 4.

An orthographic projection of the cap wall 51 onto the upper cover 2 along a leakage direction of the leak hole 3 is completely within a range of the upper cover 2. That is, a size of the cap wall 51 is smaller than or equal to a size of the upper cover 2. Along a direction perpendicular to the leakage direction, an outer peripheral side of the cap sidewall 52 is closer to the sealing cover plate than an outer peripheral side of the cap wall 41. Thus, this structure greatly removes an excessive part of the sealing cap, and then greatly reduces the influence of residual stress on the sealing cover plate 4, thereby effectively improving the sealing reliability of the sealed cavity structure 100.

In an embodiment of the present invention, the upper cover 2 includes an upper cover body 21 directly opposite to and spaced from the base 1, and an upper cover extension wall 22 extending from a periphery of the upper cover body 21 toward a direction close to the base 1 and fixed, in an abutting manner, to the base 1. The leak hole 3 passes through the upper cover body 21, the sealing cover plate 4 is attached and fixed to the upper cover body 21, and an orthographic projection of the cap wall 51 onto the upper cover 2 is completely within the range of the upper cover body 21.

In an embodiment of the present invention, an area of the cap wall 51 is smaller than an area of the upper cover body 21. That is, an excessive part of the sealing cap 5 is greatly removed, thereby greatly reducing the influence of residual stress on the sealing cover plate 4 and improving the sealing reliability.

In an embodiment of the present invention, the sealed cavity structure 100 is manufactured with the method for manufacturing a sealed cavity structure according to the present invention.

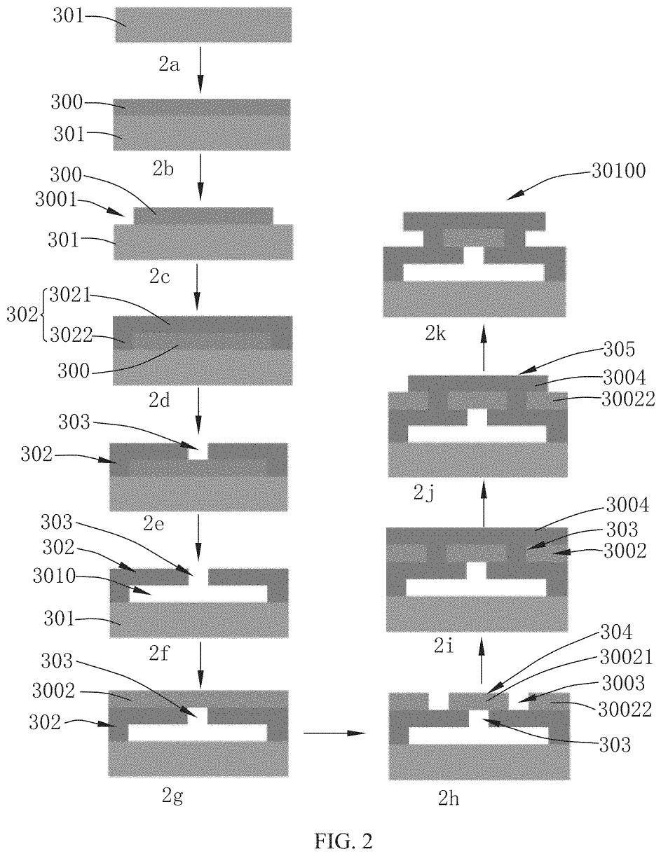

FIG. 2 is a schematic flow diagram of a method for manufacturing a sealed cavity structure according to an embodiment of the present invention. An embodiment of the present invention further provides a method for manufacturing a sealed cavity structure. In conjunction with the sealed cavity structure described above according to the present invention, the method for manufacturing a sealed cavity structure includes the following steps.

At step S1, a base 301 is provided, as shown in FIG. 2a.

At step S2, a sacrificial layer 300 is deposited on an upper surface of the base 301, as shown in FIG. 2b.

At step S3, a periphery of the sacrificial layer 300 is etched to cause a periphery of the sacrificial layer 300 to retract inward to a range of the base 301, to form an avoiding space 3001, as shown in FIG. 2c.

At step S4, an upper cover 302 is deposited on an upper surface of the sacrificial layer 300, such that the upper cover 302 supports and fixes the base 301 via the avoiding space 3001 and is completely attached to the upper surface of the sacrificial layer 300 and a peripheral side of the sacrificial layer 300, as shown in FIG. 2d.

In this step, the upper cover 302 includes an upper cover body 3021 directly opposite to and spaced from the base 301 and an upper cover extension wall 3022 extending from a periphery of the upper cover body 3021 toward a direction close to the base 301 and fixed, in an abutting manner, to the base 301. The upper cover body 3021 is pressed on the upper surface of the sacrificial layer 300. The upper cover extension wall 3022 is in a shape of a ring, and is inserted into the avoiding space 3001 and fixed to the base 301, and the upper cover extension wall 3022 is attached to the peripheral side of the sacrificial layer 300.

At step S5, the upper cover 302 is etched, such that a leak hole 303 that passes through the upper cover 302 is formed, as shown in FIG. 2e.

At step S6, the sacrificial layer 300 is released, such that the upper cover 302 and the base 301 jointly define a cavity 3010, and the leak hole 303 communicates the cavity 3010 with outside, as shown in FIG. 2f.

At step S7, a first sealing material layer 3002 is deposited on an outer surface of a side of the upper cover 302 directly opposite to the base 301, such that the first sealing material layer 3002 seals the leak hole 303, as shown in FIG. 2g.

At step S8, the first sealing material layer 3002 is etched to form a ring-shaped separation groove 3003, and the separation groove 3003 divides the first sealing material layer 3002 into a first part 30021 and a second part 30022 surrounding the first part 30021, herein, the first part 30021 serves as a sealing cover plate 304 and completely covers the leak hole 303, as shown in FIG. 2h.

At step S9, a second sealing material layer 3004 is deposited on an upper surface of the first sealing material layer 3002, and the separation groove 3003 is filled up with the second sealing material layer 3003, as shown in FIG. 2i.

At step S10, a periphery of the second sealing material layer 3004 is etched to cause the periphery of the second sealing material layer 3004 to retract inward into a range of the second part 30022, that is, an excessive part of the second sealing material layer 3004 is removed, so as to serve as a sealing cap 305, as shown in FIG. 2j.

At step S11, the second part 30022 of the first sealing material layer is released, that is, an excessive part of the first sealing material layer 3002 is removed, to obtain a sealed cavity structure 30100, as shown in FIG. 2k.

The sealed cavity structure 30100 manufactured with the method according to the present invention has the same beneficial effect as the sealed cavity structure according to the present invention, which will not be repeated herein.

Compared with the related art, according to the method for manufacturing a sealed cavity structure and a sealed cavity structure in the present invention, the leak hole is completely sealed by the sealing cover plate, a sealing cover is covered by a sealing cap to sleeve the sealing cover plate, and the structure of the sealing cap is more solid and reliable; moreover, an orthographic projection of the upper cover of the sealing cap is completely within a range of the upper cover body, equivalent to removing excessive materials of the sealing cap, realizing abutment against a peripheral side of the sealing cover plate in conjunction with the sealing cap, thereby greatly reducing an influence of residual stress on the sealing cover plate, and thus effectively improving the sealing reliability of the sealed cavity structure.

The above are merely some embodiments of the present invention. It should be pointed out herein that, for those of ordinary skill in the art, improvements can also be made without departing from a creative concept of the present invention, all of which shall fall within a scope of the present invention.

What is claimed is:

1. A method for manufacturing a sealed cavity structure, wherein the method comprises steps of:
providing a base;
depositing a sacrificial layer on an upper surface of the base;
etching a periphery of the sacrificial layer to cause the periphery of the sacrificial layer to retract inward to a range of the base to form an avoiding space;
depositing an upper cover on an upper surface of the sacrificial layer, such that the upper cover supports and fixes the base via the avoiding space and is completely attached to the upper surface of the sacrificial layer and a peripheral side of the sacrificial layer;
etching the upper cover, such that a leak hole that passes through the upper cover is formed;
releasing the sacrificial layer, such that the upper cover and the base jointly define a cavity, and the leak hole communicates the cavity with outside;
depositing a first sealing material layer on an outer surface of a side of the upper cover directly opposite to the base, such that the first sealing material layer seals the leak hole;
etching the first sealing material layer to form a ring-shaped separation groove, the ring-shaped separation groove dividing the first sealing material layer into a first part and a second part surrounding the first part, wherein the first part serves as a sealing cover plate and completely covers the leak hole;
depositing a second sealing material layer on an upper surface of the first sealing material layer, and filling up the separation groove with the second sealing material layer;
etching a periphery of the second sealing material layer to cause the periphery of the second sealing material layer to retract inward into a range of the second part, so as to serve as a sealing cap; and
releasing the second part of the first sealing material layer to obtain the sealed cavity structure.

2. A sealed cavity structure, comprising:
a base;
an upper cover, wherein the upper cover covers and is fixed to the base, and the cover and the base jointly define a cavity;
a leak hole, wherein the leak hole passes through the upper cover and communicates the cavity with outside;
a sealing cover plate, wherein the sealing cover plate is attached and fixed to an outer surface of the upper cover and completely covers the leak hole to seal the leak hole; and
a sealing cap, wherein the sealing cap comprises a cap wall pressed on a side of the sealing cover plate away from the leak hole and a cap sidewall extending from the cap wall toward a direction close to the upper cover and fixed, in an abutting manner, to the upper cover; the cap sidewall is in a shape of a ring and attached to a peripheral side of the sealing cover plate; an orthographic projection of the cap wall onto the upper cover along a leakage direction of the leak hole is completely within a range of the upper cover; and along a direction perpendicular to the leakage direction, an outer peripheral side of the cap sidewall is closer to the sealing cover plate than an outer peripheral side of the cap wall.

3. The sealed cavity structure as described in claim 2, wherein the upper cover comprises an upper cover body directly opposite to and spaced from the base and an upper cover extension wall extending from a periphery of the upper cover body toward a direction close to the base and fixed, in an abutting manner, to the base, and wherein the leak hole passes through the upper cover body, the sealing cover plate is attached and fixed to the upper cover body, and an orthographic projection of the cap wall onto the upper cover is completely within a range of the upper cover body.

4. The sealed cavity structure as described in claim 3, wherein an area of the cap wall is smaller than an area of the upper cover body.

5. The sealed cavity structure as described in claim 2, wherein the upper cover is of a cube structure, and the sealing cover plate is of a cylinder structure.

6. The sealed cavity structure as described in claim 2, wherein the sealed cavity structure is manufactured by the method for manufacturing the sealed cavity structure as described in claim 1.
